(19) United States
(12) Patent Application Publication
(10) Pub. No.: US 2006/0182886 A1
(43) Pub. Date: Aug. 17, 2006

(54) Method and system for improved delivery of a precursor vapor to a processing zone

(76) Inventors: Emmanuel P. Guidotti, Fishkill, NY (US); Kenji Suzuki, Guilderland, NY (US); Gerrit J. Leusink, Saltpoint, NY (US); Fenton R. McFeely, Ossining, NY (US)

Correspondence Address: WOOD, HERRON & EVANS, LLP (TOKYO ELECTRON), 2700 CAREW TOWER, 441 VINE STREET, CINCINNATI, OH, 45202, US

(21) Appl. No.: 11/058,676

(22) Filed: Feb. 15, 2005

(51) Int. Cl. C23C 16/00; B05C 11/00

(52) U.S. Cl. 427/252; 118/600

(57) ABSTRACT

A method and system for improved delivery of a solid precursor. A chemically inert coating is provided on system components in a precursor delivery line to reduce decomposition of a relatively unstable precursor vapor in the precursor delivery line, thereby allowing increased delivery of the precursor vapor to a processing zone for depositing a layer on a substrate. The solid precursor can, for example, be a ruthenium carbonyl or a rhenium carbonyl. The inert coating can, for example, be a CₓF_{y}-containing polymer, such as polytetrafluoroethylene or ethylene-chlorotrifluoroethylene. Other benefits of using an inert coating include easy periodic cleaning of deposits from the precursor delivery line.

### BACKGROUND OF THE INVENTION

1. Field of the Invention

The present invention relates to a method and system for thin film deposition, and more particularly to a method and system for improved precursor vapor delivery in a thin film deposition system.

2. Description of Related Art

The introduction of copper (Cu) metal into multilayer metallization schemes for manufacturing integrated circuits can necessitate the use of diffusion barriers/liners to promote adhesion and growth of the Cu layers and to prevent diffusion of Cu into the dielectric materials. Barriers/liners that are deposited onto dielectric materials can include refractive materials, such as tungsten (W), molybdenum (Mo), and tantalum (Ta), that are non-reactive and immiscible in Cu, and can offer low electrical resistivity. Current integration schemes that integrate Cu metallization and dielectric materials can require barrier/liner deposition processes at substrate temperature between about 400° C. and about 500° C., or lower.

For example, Cu integration schemes for technology nodes less than or equal to 130 nm currently utilize a low dielectric constant (low-k) inter-level dielectric, followed by a physical vapor deposition (PVD) TaN layer and Ta barrier layer, followed by a PVD Cu seed layer, and an electrochemical deposition (ECD) Cu fill. Generally, Ta layers are chosen for their adhesion properties (i.e., their ability to adhere on low-k films), and Ta/TaN layers are generally chosen for their barrier properties (i.e., their ability to prevent Cu diffusion into the low-k film).

As described above, significant effort has been devoted to the study and implementation of thin transition metal layers as Cu diffusion barriers, these studies including such materials as chromium, tantalum, molybdenum and tungsten. Each of these materials exhibits low miscibility in Cu. More recently, other materials, such as ruthenium (Ru) and rhodium (Rh), have been identified as potential barrier layers since they are expected to behave similarly to conventional refractory metals. However, the use of Ru, or Rh can permit the use of only one barrier layer, as opposed to two layers, such as Ta/TaN. This observation is due to the adhesive and barrier properties of these materials. For example, one Ru layer can replace the Ta/taN barrier layer. Moreover, current research is finding that the one Ru layer can further replace the Cu seed layer, and bulk Cu fill can proceed directly following Ru deposition. This observation is due to good adhesion between the Cu and the Ru layers.

Conventionally, Ru layers can be formed by thermally decomposing a ruthenium-containing precursor, such as a ruthenium carbonyl precursor, in a thermal chemical vapor deposition (TCVD) process. Material properties of Ru layers that are deposited by thermal decomposition of metal-carbonyl precursors (e.g., Ru₃(CO)₁₂) can deteriorate when the substrate temperature is lowered to below about 400° C. As a result, an increase in the (electrical) resistivity of the Ru layers and poor surface morphology (e.g., the formation of nodules) at low deposition temperatures has been attributed to increased incorporation of CO reaction by-products into the thermally deposited Ru layers. Both effects can be explained by a reduced CO desorption rate from the thermal decomposition of the ruthenium-carbonyl precursor at substrate temperatures below about 400° C.

Additionally, the use of metal-carbonyls, such as ruthenium carbonyl, can lead to poor deposition rates due to their low vapor pressure and the transport issues associated therewith. For instance, transport issues can include excessive decomposition of the precursor vapor on internal surfaces of the deposition system, such as on the internal surfaces of the vapor delivery system used to transport the vapor from the evaporation system to the process chamber, thus further reducing the amount of precursor vapor that reaches the substrate surface. Overall, the inventor has observed that current deposition systems suffer from such a low rate, making the deposition of such metal films impractical.

### SUMMARY OF THE INVENTION

A method and system is provided for improving the transport of precursor vapor in a thin film deposition system.

In one embodiment of the present invention, a method and system is provided for improving the transport of precursor vapor in a thin film deposition system by applying a coating to one or more internal surfaces of a vapor delivery system exposed to the precursor vapor.

In a further embodiment of the present invention, a method and system is provided for depositing a metal film from a metal-carbonyl precursor, and periodic cleaning of the coating applied to the internal surfaces is performed using an in-situ cleaning system.

According to another embodiment, a deposition system for forming a thin film on a substrate is provided comprising: a process chamber having a substrate holder configured to support and to heat the substrate, a vapor distribution system configured to introduce film precursor vapor above the substrate, and a pumping system configured to evacuate the process chamber; a film precursor evaporation system configured to evaporate a film precursor; a vapor delivery system having a first end coupled to an outlet of the film precursor evaporation system and a second end coupled to an inlet of the vapor distribution system of the process chamber; a carrier gas supply system coupled to at least one of the film precursor evaporation system or the vapor delivery system, or both, and configured to supply a carrier gas to transport the film precursor vapor in the carrier gas to the inlet of the vapor distribution system; and a coating applied to one or more internal surfaces vapor delivery system, wherein the coating is configured to reduce decomposition of the film precursor on the one or more internal surfaces.

According to yet another embodiment, a method for depositing a refractory metal film is provided comprising: applying a coating to at least one internal surface of a vapor delivery system for supplying metal precursor vapor to a process chamber of a deposition system configured to perform thermal chemical vapor deposition (TCVD) from a metal precursor; depositing the refractory metal film on one or more substrates using the deposition system; and cleaning the deposition system following the depositing of the refractory metal film on the one or more substrates using a cleaning composition formed in an in-situ cleaning system coupled to the deposition system.

### BRIEF DESCRIPTION OF THE DRAWINGS

In the accompanying drawings:

FIG. 1 depicts a schematic view of a deposition system according to an embodiment of the invention;

FIG. 2 depicts a schematic view of a deposition system according to another embodiment of the invention; and

FIG. 3 illustrates a method of depositing a thin film on a substrate according to an embodiment of the invention.

### DETAILED DESCRIPTION OF PREFERRED EMBODIMENTS

In the following description, in order to facilitate a thorough understanding of the invention and for purposes of explanation and not limitation, specific details are set forth, such as a particular geometry of the deposition system and descriptions of various components. However, it should be understood that the invention may be practiced in other embodiments that depart from these specific details.

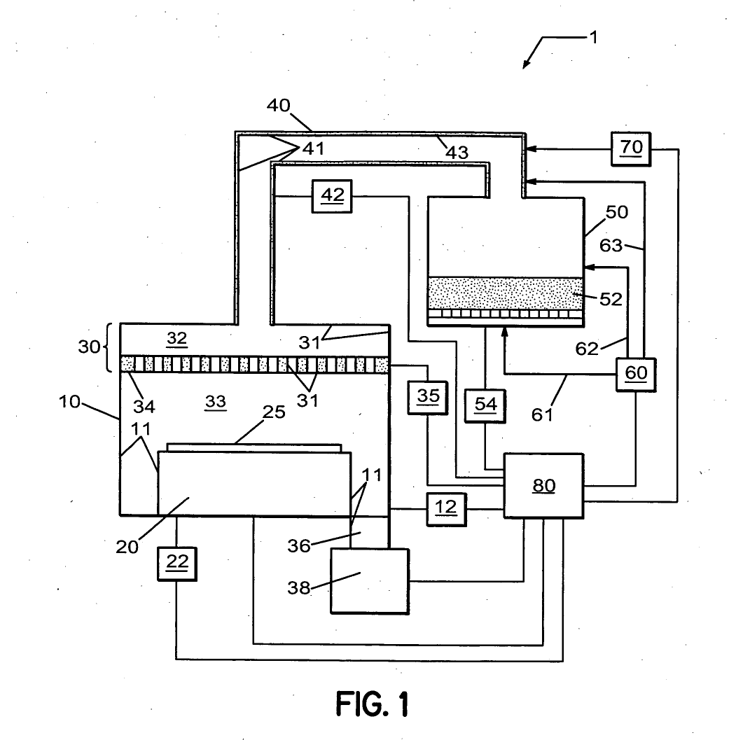

Referring now to the drawings, wherein like reference numerals designate identical or corresponding parts throughout the several views, FIG. 1 illustrates a deposition system 1 for depositing a thin film, such as a ruthenium (Ru) or a rhenium (Re) film, on a substrate according to one embodiment. The deposition system 1 comprises a process chamber 10 having a substrate holder 20 configured to support a substrate 25, upon which the thin film is formed. The process chamber 10 is coupled to a film precursor evaporation system 50 via a vapor delivery system 40.

The process chamber 10 is further coupled to a vacuum pumping system 38 through a duct 36, wherein the pumping system 38 is configured to evacuate the process chamber 10, vapor delivery system 40, and film precursor evaporation system 50 to a pressure suitable for forming the thin film on substrate 25, and suitable for evaporation of a film precursor 52 in the film precursor evaporation system 50.

Referring still to FIG. 1, the film precursor evaporation system 50 is configured to store a film precursor 52, and heat the film precursor 52 to a temperature sufficient for evaporating the film precursor 52, while introducing vapor phase precursor to the vapor delivery system 40. The film precursor 52 can, for example, comprise a metal precursor. Additionally, the film precursor 52 can, for example, comprise a solid precursor. Additionally, the film precursor 52 can, for example, comprise a solid metal precursor. Additionally, for example, the metal precursor can include a metal-carbonyl. For instance, the film precursor 52 can include ruthenium carbonyl (Ru₃(CO)₁₂), or rhenium carbonyl (Re₂(CO)₁₀). Additionally, for instance, the film precursor 52 can be W(CO)₆, Mo(CO)₆, Co₂(CO)₈, Rh₄(CO)₁₂, Cr(CO)₆, or Os₃(CO)₁₂.

In order to achieve the desired temperature for evaporating the film precursor 52 (or subliming the solid precursor), the film precursor evaporation system 50 is coupled to an evaporation temperature control system 54 configured to control the evaporation temperature. For instance, the temperature of the film precursor 52 is generally elevated to approximately 40° C. or greater in order to sublime, for instance, ruthenium carbonyl. At this temperature, the vapor pressure of the ruthenium carbonyl, for instance, ranges from approximately 1 to approximately 3 mTorr. As the film precursor is heated to cause evaporation (or sublimation), a carrier gas can be passed over the film precursor, by the film precursor, or through the film precursor, or any combination thereof. The carrier gas can include, for example, an inert gas, such as a noble gas (i.e., He, Ne, Ar, Kr, Xe), or a monoxide, such as CO, for use with metal-carbonyls, or a mixture thereof. For example, a carrier gas supply system 60 is coupled to the film precursor evaporation system 50, and it is configured to, for instance, supply the carrier gas beneath the film precursor 52 via feed line 61, or above the film precursor 52 via feed line 62. In another example, carrier gas supply system 60 is coupled to the vapor delivery system 40 and is configured to supply the carrier gas to the vapor of the film precursor 52 via feed line 63 as or after it enters the vapor delivery system 40. Although not shown, the carrier gas supply system 60 can comprise a gas source, one or more control valves, one or more filters, and a mass flow controller. For instance, the flow rate of carrier gas can range from approximately 5 sccm (standard cubic centimeters per minute) to approximately 1000 sccm. For example, the flow rate of carrier gas can range from about 10 sccm to about 200 sccm. By way of further example, the flow rate of carrier gas can range from about 20 sccm to about 100 sccm.

Downstream from the film precursor evaporation system 50, the metal precursor vapor flows with the carrier gas through the vapor delivery system 40 until it enters a vapor distribution system 30 coupled to the process chamber 10. The vapor delivery system 40 can be coupled to a vapor line temperature control system 42 in order to control the vapor line temperature and prevent decomposition of the film precursor vapor as well as condensation of the film precursor vapor. For example, the vapor line temperature can be set to a value approximately equal to or greater than the evaporation temperature. Additionally, for example, the vapor delivery system 40 can be characterized by a high conductance in excess of about 50 liters/second.

Referring again to FIG. 1, the vapor distribution system 30, coupled to the process chamber 10, comprises a plenum 32 within which the vapor disperses prior to passing through a vapor distribution plate 34 and entering a processing zone 33 above substrate 25. In addition, the vapor distribution plate 34 can be coupled to a distribution plate temperature control system 35 configured to control the temperature of the vapor distribution plate 34. For example, the temperature of the vapor distribution plate can be set to a value approximately equal to the vapor line temperature. However, it may be less, or it may be greater.

Once film precursor vapor enters the processing zone 33, the film precursor vapor thermally decomposes upon adsorption at the substrate surface due to the elevated temperature of the substrate 25, and the thin film is formed on the substrate 25. The substrate holder 20 is configured to elevate the temperature of substrate 25 by virtue of the substrate holder 20 being coupled to a substrate temperature control system 22. For example, the substrate temperature control system 22 can be configured to elevate the temperature of substrate 25 up to approximately 500° C. In one embodiment, the substrate temperature can range from about 100° C. to about 500° C. In another embodiment, the substrate temperature can range from about 300° C. to about 400° C. Additionally, process chamber 10 can be coupled to a chamber temperature control system 12 configured to control the temperature of the chamber wails.

As described above, for example, conventional systems have contemplated operating the film precursor evaporation system 50, as well as the vapor delivery system 40, within a temperature range of approximately 40-45° C. for ruthenium carbonyl in order to limit metal vapor precursor decomposition and metal vapor precursor condensation. For example, ruthenium carbonyl precursor can decompose at elevated temperatures to form by-products, such as those illustrated below:
Ru₃(CO)₁₂*(ad) [symbol] Ru₃(CO)ₓ*(ad)+(12−x)CO(g) (1)
or,
Ru₃(CO)ₓ*(ad) [symbol] 3Ru(s)+xCO(g) (2)
wherein these by-products can adsorb (ad), i.e., condense, on the interior surfaces of the deposition system 1. The accumulation of material on these surfaces can cause problems from one substrate to the next, such as process repeatability. Alternatively, for example, ruthenium carbonyl precursor can condense at depressed temperatures to cause recrystallization, viz.
Ru₃ (CO)₁₂ (g) [symbol] Ru₃(Co)₁₂*(ad) (3).

The decomposition of metal precursor vapor, or condensation of metal vapor, can occur on one or more internal surfaces within the thin film deposition system 1 that are exposed to the vapor as it is transported from the film precursor evaporation system 50 to the substrate 25. These internal surfaces include, at a minimum, internal surfaces 41 of the vapor delivery system 40. In addition, decomposition or condensation may occur on internal surfaces 31 of the vapor distribution system 30, including surfaces within plenum 32 or on the vapor distribution plate 34 or one or more orifices therein, and on internal surfaces 11 of the process chamber 10 including wall surfaces or surfaces on the substrate holder 20, as well as surfaces of duct 36. Within such systems having a small process window, the deposition rate becomes extremely low, due in part to the low vapor pressure of ruthenium carbonyl, as well as excessive decomposition of the precursor vapor on internal surfaces 11, 31, 41. For instance, the deposition rate can be as low as approximately 1 Angstrom per minute.

The inventors have observed that applying a coating to one or more of these internal surfaces 11, 31, 41 causes a reduction of, for example, vapor precursor decomposition and, as a result, an improvement of the deposition rate. According to one embodiment, a coating is applied to one or more internal surfaces 41 in the vapor delivery system 40. In a further embodiment, a coating is also applied to one or more of the internal surfaces 11, 31 in thin film deposition system 1. For example, the coating can comprise a CₓF_{y}-containing polymer coating, also referred to as a fluorocarbon coating or fluoropolymer, which is chemically inert. By way of further example, the coating can comprise polytetrafluoroethylene, such as Teflon® PTFE from DuPont or Halon® from Allied Chemical Corp., or ethylene-chlorotrifluoroethylene, such as Halar® ECTFE from Solvay Solexis. By way of further example and not limitation, other fluorocarbon coatings include fluorinated ethylene propylene, polyvinylidene fluoride, perfluoroalkoxy, polychlorotrifluoroethylene, ethylene-tetrafluoroethylene, and polyvinylfluoride. As an example, FIG. 1 illustrates a coating 43 applied to the internal surfaces 41 of the vapor delivery system 40. The coating 43 can be an adherent coating applied using at least one of spray coating, thermal spray coating, vapor deposition, or dip coating. Furthermore, the coating 43 can be formed by inserting a thin laminate sheet of material that may or may not adhere to the internal surfaces 11, 31, 41.

Thereafter, the deposition system 1 is optionally periodically cleaned using an optional in-situ cleaning system 70 coupled to, for example, the vapor delivery system 40, as shown in FIG. 1. Per a frequency determined by the operator, the in-situ cleaning system 70 can perform routine cleanings of the deposition system 1 in order to remove accumulated residue on internal surfaces 11, 31, 41 of deposition system 1 and on coatings 43. The in-situ cleaning system 70 can, for example, comprise a radical generator configured to introduce chemical radical capable of chemically reacting and removing such residue. Additionally, for example, the in-situ cleaning system 70 can, for example, include an ozone generator configured to introduce a partial pressure of ozone. For instance, the radical generator can include an upstream plasma source configured to generate oxygen or fluorine radical from oxygen (O₂), nitrogen trifluoride (NF₃), O₃, XeF₂, CIF₃, or C₃F₈ (or, more generally, CₓF_{y}), respectively. The radical generator can include an Astron® reactive gas generator, commercially available from MKS Instruments, Inc., ASTeX® Products (90 Industrial Way, Wilmington, Mass. 01887).

During operation of a cleaning process, several parameters can be set and optimized for cleaning performance. For example, the operator can set, monitor, adjust, or control the flow rate of the cleaning composition, the vapor line temperature, the temperature of the vapor distribution plate, the temperature of the substrate holder (or “dummy” substrate), the temperature of the process chamber, the pressure in the process chamber, or any combination thereof. The inventors have observed that the application of a coating 43 to one or more internal surfaces 11, 31, 41 of thin film deposition system 1 permits in-situ cleaning of the thin film deposition system 1 with a reduced risk of damage to deposition system components during cleaning.

Still referring the FIG. 1, the deposition system 1 can further include a control system 80 configured to operate and control the operation of the deposition system 1. The control system 80 is coupled to the process chamber 10, the substrate holder 20, the substrate temperature control system 22, the chamber temperature control system 12, the vapor distribution system 30, the vapor delivery system 40, the film precursor evaporation system 50, the carrier gas supply system 60, and the optional in-situ cleaning system 70.

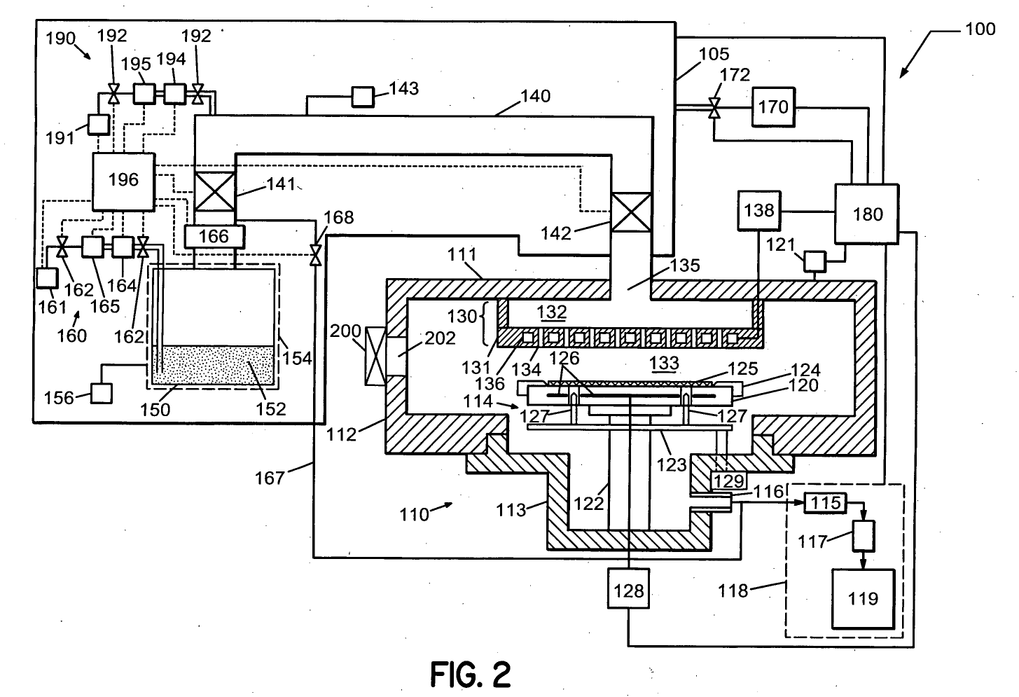

In yet another embodiment, FIG. 2 illustrates a deposition system 100 for depositing a thin film, such as a ruthenium (Ru) or a rhenium (Re) film, on a substrate. The deposition system 100 comprises a process chamber having a substrate holder 120 configured to support a substrate 125, upon which the metal film is formed. The process chamber 110 is coupled to a precursor delivery system 105 having film precursor evaporation system 150 configured to store and evaporate a film precursor 152, and a vapor delivery system 140 configured to transport film precursor vapor. One or more of the internal surfaces in deposition system 100 can include a coating such as one described above.

The process chamber 110 comprises an upper chamber section 111, a lower chamber section 112, and an exhaust chamber 113. An opening 114 is formed within lower chamber section 112, where bottom section 112 couples with exhaust chamber 113.

Referring still to FIG. 2, substrate holder 120 provides a horizontal surface to support substrate (or wafer) 125, which is to be processed. The substrate holder 120 can be supported by a cylindrical support member 122, which extends upward from the lower portion of exhaust chamber 113. An optional guide ring 124 for positioning the substrate 125 on the substrate holder 120 is provided on the edge of substrate holder 120. Furthermore, the substrate holder 120 comprises a heater 126 coupled to substrate holder temperature control system 128. The heater 126 can, for example, include one or more resistive heating elements. Alternately, the heater 126 can, for example, include a radiant heating system, such as a tungsten-halogen lamp. The substrate holder temperature control system 128 can include a power source for providing power to the one or more heating elements, one or more temperature sensors for measuring the substrate temperature or the substrate holder temperature, or both, and a controller configured to perform at least one of monitoring, adjusting, or controlling the temperature of the substrate or substrate holder.

During processing, the heated substrate 125 can thermally decompose the vapor of film precursor 152, and enable deposition of a thin film on the substrate 125. According to one embodiment, the film precursor 152 includes a metal precursor. According to another embodiment, the film precursor 152 includes a solid precursor. According to another embodiment, the film precursor 152 includes a solid metal precursor. According to another embodiment, the film precursor 152 includes a metal-carbonyl precursor. According to yet another embodiment, the film precursor 152 can be a ruthenium-carbonyl precursor, for example Ru₃(CO)₁₂. According to yet another embodiment of the invention, the film precursor 152 can be a rhenium carbonyl precursor, for example Re₂(CO)₁₀. As will be appreciated by those skilled in the art of thermal chemical vapor deposition, other ruthenium carbonyl precursors and rhenium carbonyl precursors can be used without departing from the scope of the invention. In yet another embodiment, the film precursor 152 can be W(CO)₆, Mo(CO)₆, Co₂(CO)₈, Rh₄(CO)₁₂, Cr(CO)₆, or Os₃(CO)₁₂, or the like. The substrate holder 120 is heated to a pre-determined temperature that is suitable for depositing the desired Ru, Re or other metal layer onto the substrate 125. Additionally, a heater (not shown), coupled to a chamber temperature control system 121, can be embedded in the walls of process chamber 110 to heat the chamber walls to a predetermined temperature. The heater can maintain the temperature of the walls of process chamber 110 from about 40° C. to about 150° C., for example from about 40° C. to about 80° C. A pressure gauge (not shown) is used to measure the process chamber pressure.

Also shown in FIG. 2, a vapor distribution system 130 is coupled to the upper chamber section 111 of process chamber 110. Vapor distribution system 130 comprises a vapor distribution plate 131 configured to introduce precursor vapor from vapor distribution plenum 132 to a processing zone 133 above substrate 125 through one or more orifices 134.

Furthermore, an opening 135 is provided in the upper chamber section 111 for introducing a vapor precursor from vapor delivery system 140 into vapor distribution plenum 132. Moreover, temperature control elements 136, such as concentric fluid channels configured to flow a cooled or heated fluid, are provided for controlling the temperature of the vapor distribution system 130, and thereby prevent the decomposition of the film precursor inside the vapor distribution system 130. For instance, a fluid, such as water, can be supplied to the fluid channels from a vapor distribution temperature control system 138. The vapor distribution temperature control system 138 can include a fluid source, a heat exchanger, one or more temperature sensors for measuring the fluid temperature or vapor distribution plate temperature or both, and a controller configured to control the temperature of the vapor distribution plate 131 from about 20° C. to about 100° C.

As illustrated in FIG. 2, a film precursor evaporation system 150 is configured to hold film precursor 152 and evaporate (or sublime) the film precursor 152 by elevating the temperature of the film precursor 152. A precursor heater 154 is provided for heating the film precursor 152 to maintain the film precursor 152 at a temperature that produces a desired vapor pressure of film precursor 152. The precursor heater 154 is coupled to an evaporation temperature control system 156 configured to control the temperature of the film precursor 152. For example, the precursor heater 154 can be configured to adjust the temperature of the film precursor 152 (or evaporation temperature) to be greater than or equal to approximately 40° C. Alternatively, the evaporation temperature is elevated to be greater than or equal to approximately 50° C. For example, the evaporation temperature is elevated to be greater than or equal to approximately 60° C. In one embodiment, the evaporation temperature is elevated to range from approximately 60-150° C., and in another embodiment, to range from approximately 60-90° C.

As the film precursor 152 is heated to cause evaporation (or sublimation), a carrier gas can be passed over the film precursor, by the film precursor, or through the film precursor, or any combination thereof. The carrier gas can include, for example, an inert gas, such as a noble gas (i.e., He, Ne, Ar, Kr, Xe), or a monoxide, such as CO, for use with metal-carbonyls, or a mixture thereof. For example, a carrier gas supply system 160 is coupled to the film precursor evaporation system 150, and it is configured to, for instance, supply the carrier gas beneath the film precursor, or above the film precursor. Although not shown in FIG. 2, carrier gas supply system 160 can also or alternatively be coupled to the vapor delivery system 140 to supply the carrier gas to the vapor of the film precursor 152 as or after it enters the vapor delivery system 140. The carrier gas supply system 160 can comprise a gas source 161, one or more control valves 162, one or more filters 164, and a mass flow controller 165. For instance, the flow rate of carrier gas can range from approximately 5 sccm (standard cubic centimeters per minute) to approximately 1000 sccm. In one embodiment, the flow rate of carrier gas can range from about 10 sccm to about 200 sccm. In another embodiment, the flow rate of carrier gas can range from about 20 sccm to about 100 sccm.

Additionally, a sensor 166 is provided for measuring the total gas flow from the film precursor evaporation system 150. The sensor 166 can, for example, comprise a mass flow controller, and the amount of film precursor vapor delivered to the process chamber 110 can be determined using sensor 166 and mass flow controller 165. Alternately, the sensor 166 can comprise a light absorption sensor to measure the concentration of the film precursor in the gas flow to the process chamber 110.

A bypass line 167 can be located downstream from sensor 166, and it can connect the vapor delivery system 140 to an exhaust line 116. Bypass line 167 is provided for evacuating the vapor delivery system 140, and for stabilizing the supply of the metal precursor to the process chamber 110. In addition, a bypass valve 168, located downstream from the branching of the vapor precursor delivery system 140, is provided on bypass line 167.

Referring still to FIG. 2, the vapor delivery system 140 comprises a high conductance vapor line having first and second valves 141 and 142 respectively. Additionally, the vapor delivery system 140 can further comprise a vapor line temperature control system 143 configured to heat the vapor delivery system 140 via heaters (not shown). The temperatures of the vapor lines can be controlled to avoid condensation of the metal precursor in the vapor line. The temperature of the vapor lines can be greater than or equal to 40° C. Additionally, the temperature of the vapor lines can be controlled from about 40° C. to about 150° C., or from about 40° C. to about 90° C. For example, the vapor line temperature can be set to a value approximately equal to or greater than the evaporation temperature.

Moreover, dilution gases can be supplied from a dilution gas supply system 190. The dilution gas can include, for example, an inert gas, such as a noble gas (i.e., He, Ne, Ar, Kr, Xe), or a monoxide, such as CO, for use with metal-carbonyls, or a mixture thereof. For example, the dilution gas supply system 190 is coupled to the vapor delivery system 140, and it is configured to, for instance, supply the dilution gas to the film precursor vapor. The dilution gas supply system 190 can comprise a gas source 191, one or more control valves 192, one or more filters 194, and a mass flow controller 195. For instance, the flow rate of carrier gas can range from approximately 5 sccm (standard cubic centimeters per minute) to approximately 1000 sccm.

Mass flow controllers 165 and 195, and valves 162, 192, 168, 141, and 142 are controlled by controller 196, which controls the supply, shutoff, and the flow of the carrier gas, the film precursor vapor, and the dilution gas. Sensor 166 is also connected to controller 196 and, based on output of the sensor 166, controller 196 can control the carrier gas flow through mass flow controller 165 to obtain the desired film precursor vapor flow to the process chamber 110.

Furthermore, as described above, and as shown in FIG. 2, an optional in-situ cleaning system 170 is coupled to the precursor delivery system 105 of deposition system 100 through cleaning valve 172. For instance, the in-situ cleaning system 170 can be coupled to the vapor delivery system 140. The in-situ cleaning system 170 can, for example, comprise a radical generator configured to introduce chemical radical capable of chemically reacting and removing such residue. Additionally, for example, the in-situ cleaning system 170 can, for example, include an ozone generator configured to introduce a partial pressure of ozone. For instance, the radical generator can include an upstream plasma source configured to generate oxygen or fluorine radical from oxygen (O₂), nitrogen trifluoride (NF₃), ClF₃, O₃, XeF₂, or C₃F₈ (or, more generally, CₓF_{y}), respectively. The radical generator can include an Astron® reactive gas generator, commercially available from MKS Instruments, Inc., ASTeX® Products (90 Industrial Way, Wilmington, Mass. 01887).

As illustrated in FIG. 2, the exhaust line 116 connects exhaust chamber 113 to pumping system 118. A vacuum pump 119 is used to evacuate process chamber 110 to the desired degree of vacuum, and to remove gaseous species from the process chamber 110 during processing. An automatic pressure controller (APC) 115 and a trap 117 can be used in series with the vacuum pump 119. The vacuum pump 119 can include a turbo-molecular pump (TMP) capable of a pumping speed up to 5000 liters per second (and greater). Alternately, the vacuum pump 119 can include a dry roughing pump. During processing, the carrier gas, dilution gas, or film precursor vapor, or any combination thereof, can be introduced into the process chamber 110, and the chamber pressure can be adjusted by the APC 115. For example, the chamber pressure can range from approximately 1 mTorr to approximately 500 mTorr, and in a further example, the chamber pressure can range from about 5 mTorr to 50 mTorr. The APC 115 can comprise a butterfly-type valve or a gate valve. The trap 117 can collect unreacted precursor material, and by-products from the process chamber 110.

Referring back to the substrate holder 120 in the process chamber 110, as shown in FIG. 2, three substrate lift pins 127 (only two are shown) are provided for holding, raising, and lowering the substrate 125. The substrate lift pins 127 are coupled to plate 123, and can be lowered to below to the upper surface of substrate holder 120. A drive mechanism 129 utilizing, for example, an air cylinder provides means for raising and lowering the plate 123. Substrate 125 can be transferred into and out of process chamber 110 through gate valve 200 and chamber feed-through passage 202 via a robotic transfer system (not shown), and received by the substrate lift pins 127. Once the substrate 125 is received from the transfer system, it can be lowered to the upper surface of the substrate holder 120 by lowering the substrate lift pins 127.

Referring again to FIG. 2, a controller 180 includes a microprocessor, a memory, and a digital I/O port capable of generating control voltages sufficient to communicate and activate inputs of the processing system 100 as well as monitor outputs from the processing system 100. Moreover, the processing system controller 180 is coupled to and exchanges information with process chamber 110; precursor delivery system 105, which includes controller 196, vapor line temperature control system 143, and evaporation temperature control system 156; vapor distribution temperature control system 138; vacuum pumping system 118; and substrate holder temperature control system 128. In the vacuum pumping system 118, the controller 180 is coupled to and exchanges information with the automatic pressure controller 115 for controlling the pressure in the process chamber 110. A program stored in the memory is utilized to control the aforementioned components of deposition system 100 according to a stored process recipe. One example of processing system controller 180 is a DELL PRECISION WORKSTATION 610™, available from Dell Corporation, Dallas, Tex. The controller 180 may also be implemented as a general-purpose computer, digital signal process, etc.

Controller 180 may be locally located relative to the deposition system 100, or it may be remotely located relative to the deposition system 100 via an internet or intranet. Thus, controller 180 can exchange data with the deposition system 100 using at least one of a direct connection, an intranet, or the internet. Controller 180 may be coupled to an intranet at a customer site (i.e., a device maker, etc.), or coupled to an intranet at a vendor site (i.e., an equipment manufacturer). Furthermore, another computer (i.e., controller, server, etc.) can access controller 180 to exchange data via at least one of a direct connection, an intranet, or the internet.

As described above, for example, conventional systems have contemplated operating the metal precursor evaporation system, as well as the vapor delivery system, within a temperature range of approximately 4045° C. for ruthenium carbonyl in order to limit metal vapor precursor decomposition and metal vapor precursor condensation. However, due to the low vapor pressure of metal-carbonyls, such as ruthenium carbonyl or rhenium carbonyl, at this temperature, the deposition rate of, for example, ruthenium or rhenium, is very low. In order to improve the deposition rate, the evaporation temperature is raised above about 40° C., for example above about 50° C. Following high temperature evaporation of the metal precursor for one or more substrates, the deposition system is periodically cleaned to remove residues formed on internal surfaces of the deposition system.

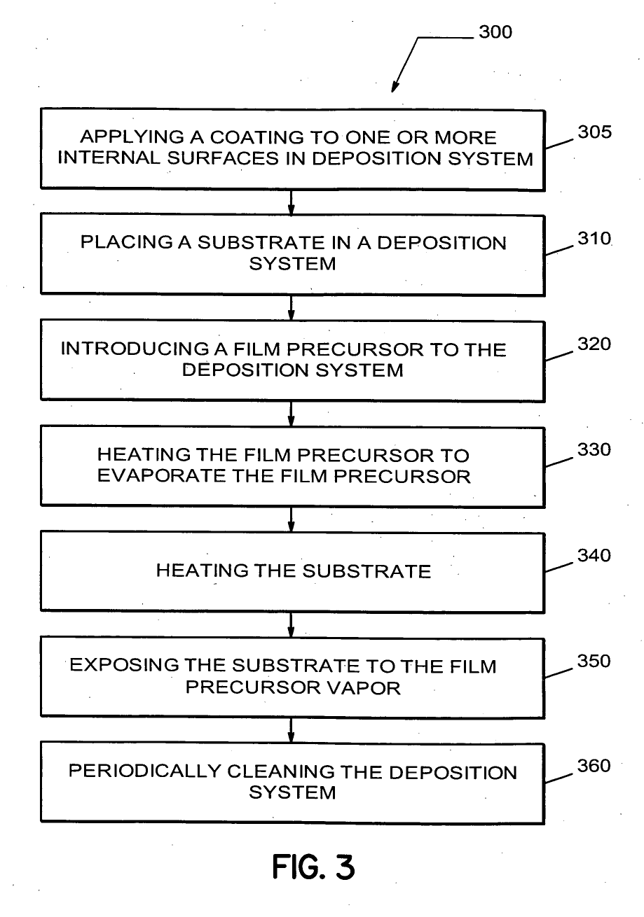

Referring now to FIG. 3, a method of depositing a refractory metal film on a substrate is described. A flow chart 300 is used to illustrate the steps in depositing the metal film in a deposition system in accordance with the method of the present invention. In 305, the metal film deposition begins with disposing a coating on one or more surfaces in the deposition system including at least one internal surface of the vapor delivery system. A coating may further be applied to the internal surfaces of the vapor distribution system, which is coupled to the vapor delivery system, and to other surfaces within the process chamber upon which vapor condensate may accumulate. For example, the coating comprises a CₓF_{y}-containing polymer coating. By way of further example, the coating may comprise polytetrafluoroethylene. In 310, a substrate is placed in the deposition system for forming the metal film on the substrate. For example, the deposition system can include any one of the depositions systems described above in FIGS. 1 and 2. The deposition system can include a process chamber for facilitating the deposition process, and a substrate holder coupled to the process chamber and configured to support the substrate. Then, in 320, a metal precursor is introduced to the deposition system. For instance, the metal precursor is introduced to a film precursor evaporation system coupled to the process chamber via a vapor delivery system. Additionally, for instance, the vapor delivery system can be heated.

In 330, the metal precursor is heated to form a metal precursor vapor. The metal precursor vapor can then be transported to the process chamber through the vapor delivery system. In 340, the substrate is heated to a substrate temperature sufficient to decompose the metal precursor vapor, and, in 350, the substrate is exposed to the metal precursor vapor. Steps 310 to 350 may be repeated successively a desired number of times to deposit a metal film on a desired number of substrates.

Following the deposition of the refractory metal film on one or more substrates, the deposition system is optionally periodically cleaned in 360 by introducing a cleaning composition from an in-situ cleaning system coupled to the deposition system, and in particular, coupled to at least the vapor delivery system for providing the cleaning composition to the vapor delivery system, and optionally to the process chamber. The cleaning composition can, for example, include a halogen containing radical, fluorine radical, oxygen radical, ozone, or a combination thereof. The in-situ cleaning system can, for example, include a radical generator, or an ozone generator. When a cleaning process is performed, a “dummy” substrate can be utilized to protect the substrate holder. Furthermore, the film precursor evaporation system, the vapor delivery system, the process chamber, the vapor distribution system, or the substrate holder, or any combination thereof can be heated.

Although only certain exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

What is claimed is:

1. A deposition system for forming a thin film on a substrate comprising:
a process chamber having a substrate holder configured to support said substrate and heat said substrate, a vapor distribution system configured to introduce film precursor vapor above said substrate, and a pumping system configured to evacuate said process chamber;
a film precursor evaporation system configured to evaporate a film precursor;
a vapor delivery system having a first end coupled to an outlet of said film precursor evaporation system and a second end coupled to an inlet of said vapor distribution system of said process chamber;
a carrier gas supply system coupled to at least one of said film precursor evaporation system or said vapor delivery system, or both, and configured to supply a carrier gas to transport said film precursor vapor in said carrier gas to said inlet of said vapor distribution system; and
a coating applied to one or more internal surfaces in said vapor delivery system, wherein said coating is configured to reduce decomposition of said film precursor on said one or more internal surfaces.

2. The deposition system of claim 1, wherein said film precursor evaporation system is configured to heat said film precursor to an evaporation temperature greater than or equal to approximately 40° C.

3. The deposition system of claim 1, wherein said vapor delivery system is configured to heat a vapor line therein to a temperature greater than or equal to approximately 40° C.

4. The deposition system of claim 1, further comprising:
a controller coupled to said process chamber, said vapor delivery system, and said film precursor evaporation system, and configured to perform at least one of setting, monitoring, adjusting, or controlling one or more of a substrate temperature, an evaporation temperature, a vapor line temperature, a flow rate of saidcarrier gas, ora pressure in said process chamber.

5. The deposition system of claim 1, further comprising:
an in-situ cleaning system coupled to said vapor delivery system and configured to provide a cleaning composition to said vapor delivery system and said process chamber, wherein said cleaning composition is configured to remove residue formed on said internal surfaces of said vapor delivery system and internal surfaces of said process chamber.

6. The deposition system of claim 6, further comprising:
a controller coupled to said in-situ cleaning system, and configured to perform at least one of setting, monitoring, adjusting, or controlling one or more of a flow rate of said cleaning composition or a pressure of said process chamber.

7. The deposition system of claim 6, wherein said in-situ cleaning system comprises a radical generator configured to provide said cleaning composition comprising at least one of fluorine radical or oxygen radical.

8. The deposition system of claim 6, wherein said radical generator is configured to dissociate O₂, CIF₃, NF₃, O₃, or C₃F₈, or any combination thereof.

9. The deposition system of claim 6, wherein said in-situ cleaning system comprises an ozone generator configured to provide said cleaning composition comprising ozone.

10. The deposition system of claim 1, wherein said film precursor evaporation system is configured to evaporate a metal-carbonyl precursor.

11. The deposition system of claim 1, wherein said vapor delivery system is characterized by a high conductance in excess of about 50 liters/second.

12. The deposition system of claim 1, wherein said coating comprises a CₓF_{y}-containing polymer film, where x and y are integers greater than or equal to unity.

13. The deposition system of claim 1, wherein said coating comprises one or more of polytetrafluoroethylene, fluorinated ethylene propylene, polyvinylidene fluoride, perfluoroalkoxy, polychlorotrifluoroethylene, ethylene-chlorotrifluoroethylene, ethylene-tetrafluoroethylene, and polyvinylfluoride.

14. The deposition system of claim 1, wherein said coating comprises polytetrafluoroethylene.

15. The deposition system of claim 1, wherein said coating is an adherent coating applied using at least one of spray coating, thermal spray coating, dip coating, or vapor deposition.

16. The deposition system of claim 1, wherein said coating comprises a laminate positioned adjacent said one or more internal surfaces.

17. The deposition system of claim 1, further comprising said coating applied to one or more internal surfaces within said process chamber.

18. A method for depositing a refractory metal film comprising:
applying a coating to at least one internal surface of a vapor delivery system for supplying metal precursor vapor to a process chamber of a deposition system configured to perform thermal chemical vapor deposition (TCVD) from a metal precursor;
depositing said refractory metal film on one or more substrates using said deposition system; and
cleaning said deposition system following said depositing of said refractory metal film on said one or more substrates using a cleaning composition formed in an in-situ cleaning system coupled to said deposition system.

19. The method of claim 18, wherein said depositing said refractory metal film comprises placing one substrate of said one or more substrates in said process chamber on a substrate holder coupled to said process chamber and configured to support said one substrate;
introducing said metal precursor to a metal precursor evaporation system coupled to said process chamber via said vapor delivery system;
heating said metal precursor in said metal precursor evaporation system to form said metal precursor vapor;
heating said one substrate to a substrate temperature sufficient to decompose said metal precursor vapor; and
exposing said one substrate to said metal precursor vapor.

20. The method of claim 19, wherein said introducing said metal precursor includes introducing a ruthenium precursor.

21. The method of claim 19, wherein said introducing said metal precursor includes introducing a rhenium precursor.

22. The method of claim 19, wherein said introducing said metal precursor comprises introducing a solid metal precursor.

23. The method of claim 19, wherein said introducing from said metal precursor comprises introducing a metal-carbonyl.

24. The method of claim 19, wherein said introducing said metal precursor comprises introducing ruthenium carbonyl (Ru₃(CO)₁₂).

25. The method of claim 19, wherein said introducing said metal precursor comprises introducing rhenium carbonyl (Re₂(CO)₁₀).

26. The method of claim 19, wherein heating said one substrate is to a substrate temperature greater than or equal to about 10° C.

27. The method of claim 19, wherein said heating said metal precursor is to an evaporation temperature greater than or equal to about 40° C.

28. The method of claim 27, wherein said heating said metal precursor is to an evaporation temperature greater than or equal to about 50° C.

29. The method of claim 27, wherein said heating said metal precursor is to an evaporation temperature ranging from about 50° C. to about 150° C.

30. The method of claim 27, wherein said heating said metal precursor is to an evaporation temperature ranging from about 60° C. to about 90° C.

31. The method of claim 18, wherein said cleaning said deposition system includes using a radical generator or an ozone generator to form said cleaning composition.

32. The method of claim 18, wherein said cleaning said deposition system comprises using one or more of a fluorine radical, oxygen radical, or ozone cleaning composition.

33. The method of claim 19, wherein said introducing said metal precursor comprises introducing one of W(CO)₆, Mo(CO)₆, Co₂(CO)₈, Rh₄(CO)₁₂, Cr(CO)₆, or OS₃(CO)₁₂.

34. The method of claim 18, wherein said applying said coating comprises applying a CₓF_{y}-containing polymer coating, where x and y represent integers greater than or equal to unity.

35. The method of claim 18, wherein said applying said coating comprises applying a polymer coating selected from the group consisting of: polytetrafluoroethylene, fluorinated ethylene propylene, polyvinylidene fluoride, perfluoroalkoxy, polychlorotrifluoroethylene, ethylene-chlorotrifluoroethylene, ethylene-tetrafluoroethylene, and polyvinylfluoride.

36. The method of claim 18, wherein said applying said coating comprises inserting a laminate adjacent said at least one internal surface.

37. The method of claim 18, wherein said applying said component comprises applying a polytetrafluoroethylene polymer coating.

38. The method of claim 19, further comprising applying said coating to at least one internal surface of said process chamber.

39. The method of claim 19, further comprising applying said coating to at least one internal surface of a vapor distribution system in said process chamber.
